(19) United States
(12) Patent Application Publication
(10) Pub. No.: US 2013/0180852 A1
(43) Pub. Date: Jul. 18, 2013

(54) ELECTRODE, SENSOR CHIP USING THE SAME AND METHOD OF MAKING THE SAME

(71) Applicants: Chien-Chong Hong, Hsinchu County (TW); Hong-Ren Jian, Nantou County (TW); Kuo-Ti Peng, Chiayi County (TW); I-Ming Chu, Hsinchu (TW)

(72) Inventors: Chien-Chong Hong, Hsinchu County (TW); Hong-Ren Jian, Nantou County (TW); Kuo-Ti Peng, Chiayi County (TW); I-Ming Chu, Hsinchu (TW)

(21) Appl. No.: 13/618,200

(22) Filed: Sep. 14, 2012

(30) Foreign Application Priority Data
Jan. 13, 2012 (TW) 101101445

(51) Int. Cl. C23F 17/00; C23C 14/34; G01N 27/30; C25B 11/04; C25D 13/12; B05D 1/00; B82Y 99/00; B82Y 30/00

(52) U.S. Cl. 204/400; 204/484; 204/486; 204/290.08; 977/773; 977/742; 977/700; 977/752; 977/902

(57) ABSTRACT

A working electrode includes a conducting layer, a carbon nanotube layer electrophoretically deposited on the conducting layer; and a gold nanoparticle layer sputter-deposited on the carbon nanotube layer. A sensor chip having the working electrode and a method of fabricating the working electrode are also disclosed.

### CROSS-REFERENCE TO RELATED APPLICATION

This application claims priority of Taiwanese Patent Application No. 101101445 filed on Jan. 13, 2012.

### BACKGROUND OF THE INVENTION

1. Field of the Invention

The present invention relates to an electrode, and more particularly to an electrode having carbon nanotubes, a sensor using the electrode, and a fabrication method thereof.

2. Description of the Related Art

Nanocapsules are commonly used to encapsulate drugs for controlled delivery of drugs to target sites inside patients' bodies. Generally, nanocapsules are temperature sensitive and can decompose gradually and release drugs when affected by temperature.

Electrochemical sensors are used in evaluating the rate of drug release from nanocapsules in order to ensure that a controlled dose of drug is administered and undesirable side effects are avoided. An electrochemical sensor typically includes a working electrode, a reference electrode and an auxiliary electrode. Working electrodes having carbon nanotubes are well known in the art. Examples of such working electrodes are disclosed in US 20090008712, US 20090266580, and C. C. Hong, et. al., “An Antibiotic Biosensor Platform for Preclinical Evaluation of Drug Release Profile of Nanocapsules,” Proceedings of the 14^{th} International Conference on Micro Total Analysis System (micro-TAS 2010), Groningen, NETHERLANDS, Oct. 3-7, 2010, pp. 1670-1672. In Hong et. al, a carbon nanotube layer is deposited on a gold layer by a drop coating method.

### SUMMARY OF THE INVENTION

An object of the present invention is to provide a novel electrode having a gold-carbon nanotube hybrid structure.

Another object of the present invention is to provide a sensor chip with the novel electrode.

Still another object of the invention is to provide a method of fabricating the novel electrode.

According to one aspect of the invention, a working electrode, comprises a conducting layer; a carbon nanotube layer electrophoretically deposited on the conducting layer; and a gold nanoparticle layer sputter-deposited on the carbon nanotube layer.

According to another aspect of the invention, a method of making a working electrode, comprises: forming a conducting layer on a substrate; depositing electrophoretically a carbon nanotube layer on the conducting layer; and sputter-depositing a gold nanoparticle layer on the carbon nanotube layer.

According to still another aspect of the invention, a sensor chip for detecting a drug released from nanocapsules in a solution, comprises a housing unit including a micro-channel, a partition piece, an extraction hole, and an injection hole unit. The micro-channel has an injection region communicated with the injection hole unit and adapted to receive the nanocapsules and the solution, an extraction region communicated with the extraction hole, and a measure region disposed between the injection region and the extraction region. The partition piece is disposed in the injection region for preventing the nanocapsules from flowing to the measure region while permitting the drug to flow to the measure region.

The sensor chip further comprises a sensing electrode unit disposed in the housing unit and includes a working electrode exposed to the measure region.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of a sensor chip according to a preferred embodiment of the present invention;

FIG. 2 is an exploded view of the sensor chip;

FIG. 3 is a plan view showing a sensing electrode unit of the sensor chip;

FIG. 4 is an elevation view of a working electrode of the sensing electrode unit;

FIG. 5 is a flow diagram illustrating a fabrication method for the working electrode;

FIG. 6 is a schematic view illustrating an electrophoretic deposition of a carbon nanotube layer on the working electrode;

FIG. 7 shows a circuit for supplying a constant current used in the electrophoretic deposition;

FIG. 8 shows a graph of capacitance change values plotted as a function of duration of electrophoretic deposition;

FIG. 9 shows an SEM image of a carbon nanotube layer of the working electrode after the carbon nanotube layer is washed;

FIG. 10 shows an SEM image of a carbon nanotube layer of the working electrode before the carbon nanotube layer is washed;

FIG. 11 illustrates an adhesion test conducted for the carbon nanotube layer of the working electrode;

FIG. 12 shows a graph of capacitance change values plotted as a function of stirring duration for the adhesion test;

FIG. 13 shows a graph of current values plotted as a function of teicoplanin concentration for an electrode having a bare gold layer;

FIG. 14 shows a graph of current values plotted as a function of teicoplanin concentration for an electrode having a carbon nanotube layer deposited by drop coating; and

FIG. 15 shows a graph of current values plotted as a function of teicoplanin concentration for an electrode having a carbon nanotube layer deposited electrophoretically but without gold nanoparticles;

FIG. 16 shows a graph of current values plotted as a function of teicoplanin concentration for the working electrode according to the present invention; and

FIG. 17 shows graphs of teicoplanin concentration as a function of duration.

### DETAILED DESCRIPTION OF THE PREFERRED EMBODIMENTS

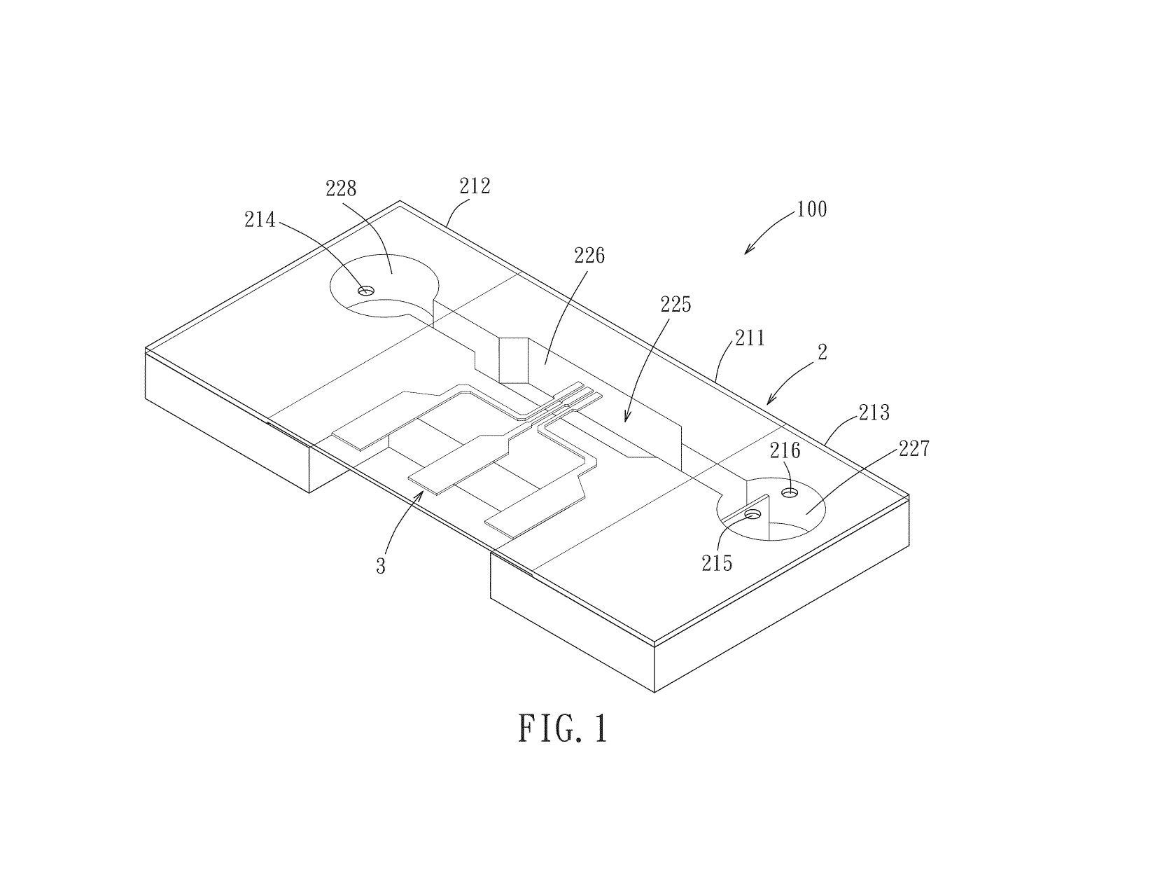

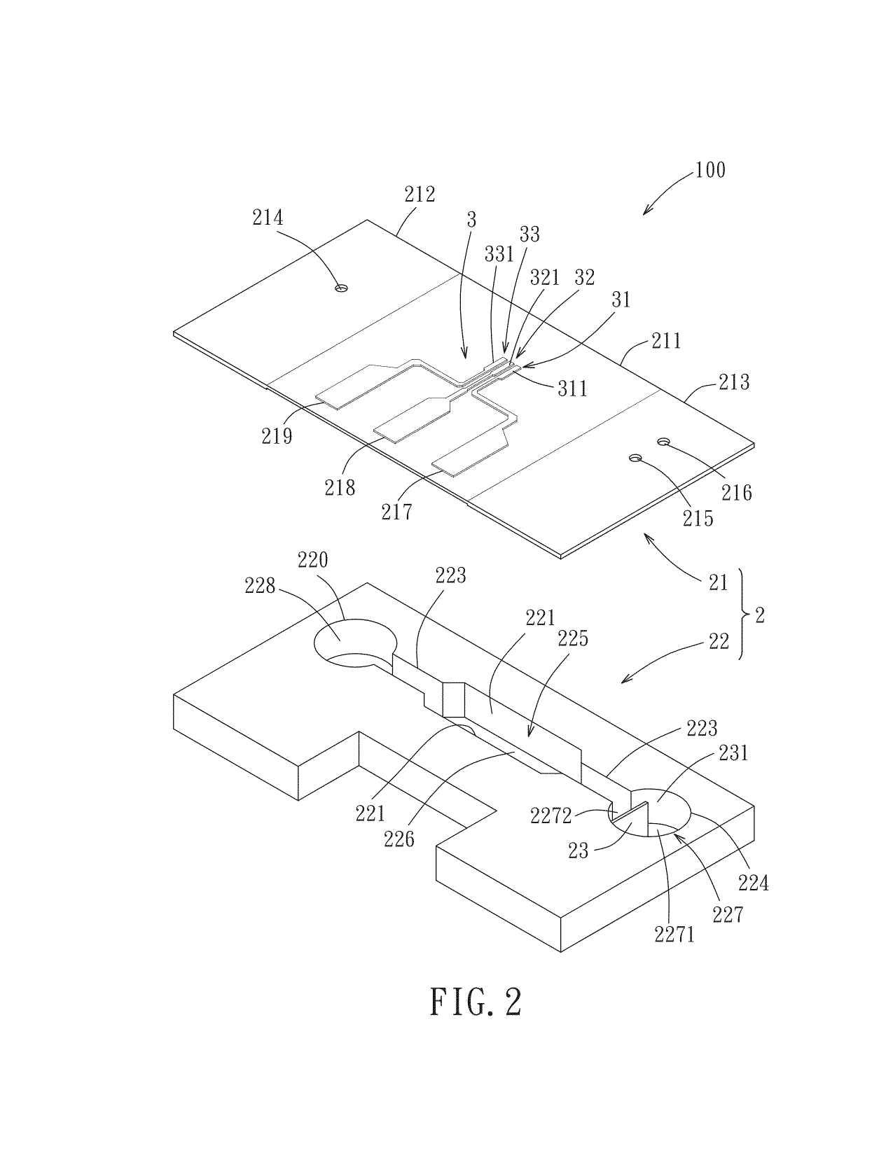

Referring to FIGS. 1 and 2, a sensor chip 100 according to a preferred embodiment of the present invention includes a housing unit 2, and a sensing electrode unit 3.

The housing unit 2 includes an upper housing part 21, and a lower housing part 22. The upper housing part 21 has a substrate plate 211, and first and second cover parts 212, 213 disposed respectively at two opposite sides of the substrate plate 211. The sensing electrode unit 3 is formed on the substrate plate 211. The first cover part 212 has an extraction hole 214. The second cover part 213 has first and second injection holes 215 and 216.

The upper housing part 21 is stacked on and bonded to the lower housing part 22. The lower housing part 22 is formed with a micro-channel 225, which includes a measure region 226, an injection region 227, and an extraction region 228. The measure region 226 is defined by two elongated walls 221. The injection region 227 is surrounded by a rounded injection region wall 224 and is covered by the second cover part 213. The extraction region 228 is defined by a rounded extraction region wall 220 and is covered by the first cover part 212. The measure region 226 has two opposite narrowed connection parts 223 respectively connected to the injection and extraction regions 227, 228.

The injection region 227 is a rounded region. A partition piece 23 is disposed across the injection region 227 to divide the injection region 227 into first and second regions 2271, 2272. The partition piece 23 has one end contacting a portion of the injection region wall 224 and another end spaced apart from the injection region wall 224 to define a passage 231 together with the injection region wall 224. The passage 231 is connected fluidly between the first and second regions 2271, 2272. The first region 2271 is distal from the measure region 226 and is aligned with the first injection hole 215. The second region 2272 is proximate to the measure region 226 and interposes between the first region 2271 and the measure region 226. The second injection hole 216 is aligned with the passage 231.

While the passage 231 is defined by the end of the partition piece 23 and the injection region wall 224 in this embodiment, the passage 231 may also be formed between the two ends of the partition piece 23.

The substrate plate 211 is made of glass. The first and second cover parts 212, 213 and the lower housing part 22 are made of a photo-curable plastic material.

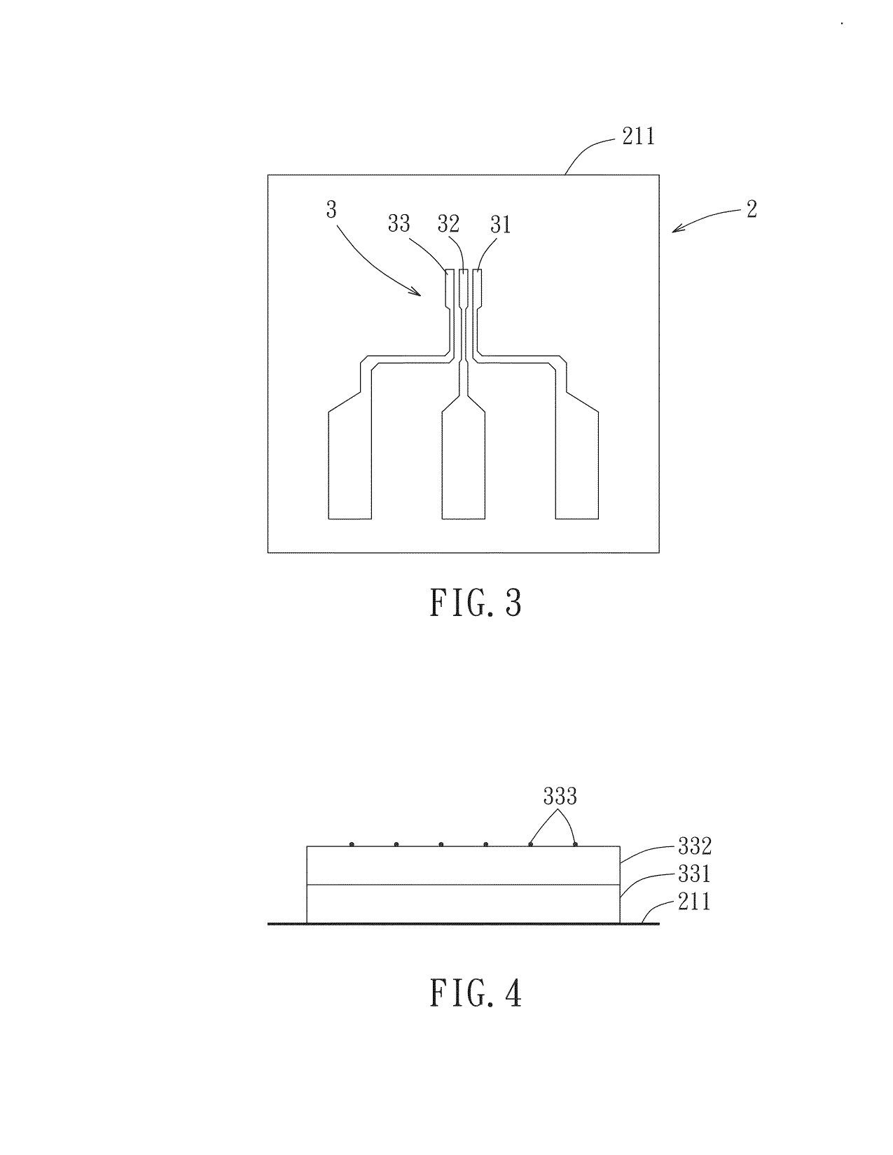

Referring to FIGS. 3 and 4, the sensing electrode unit 3 is exposed to the measure region 226, and includes a reference electrode 31, an auxiliary electrode 32 and a working electrode 33, all of which are disposed between the elongated walls 221 of the measure region 226. The working electrode 33 has a conducting layer 331 formed on the substrate plate 211, a carbon nanotube layer 332 electrophoretically deposited on the conducting layer 331, and a gold nanoparticle layer 333 sputter-deposited on the carbon nanotube layer 332. The reference electrode 31 has a conducting layer 311 formed on the substrate plate 211. The auxiliary electrode 32 has a conducting layer 321 formed on the substrate plate 211. The conducting layers 311, 321, 331 are bare gold layers. The thickness of the carbon nanotube layer 332 may be 200-500 nm. In an embodiment, the carbon nanotube layer 332 includes multi-wall carbon nanotubes, and the thickness thereof is about 260 nm. The thickness of the gold nanoparticle layer 333 is about 20 nm.

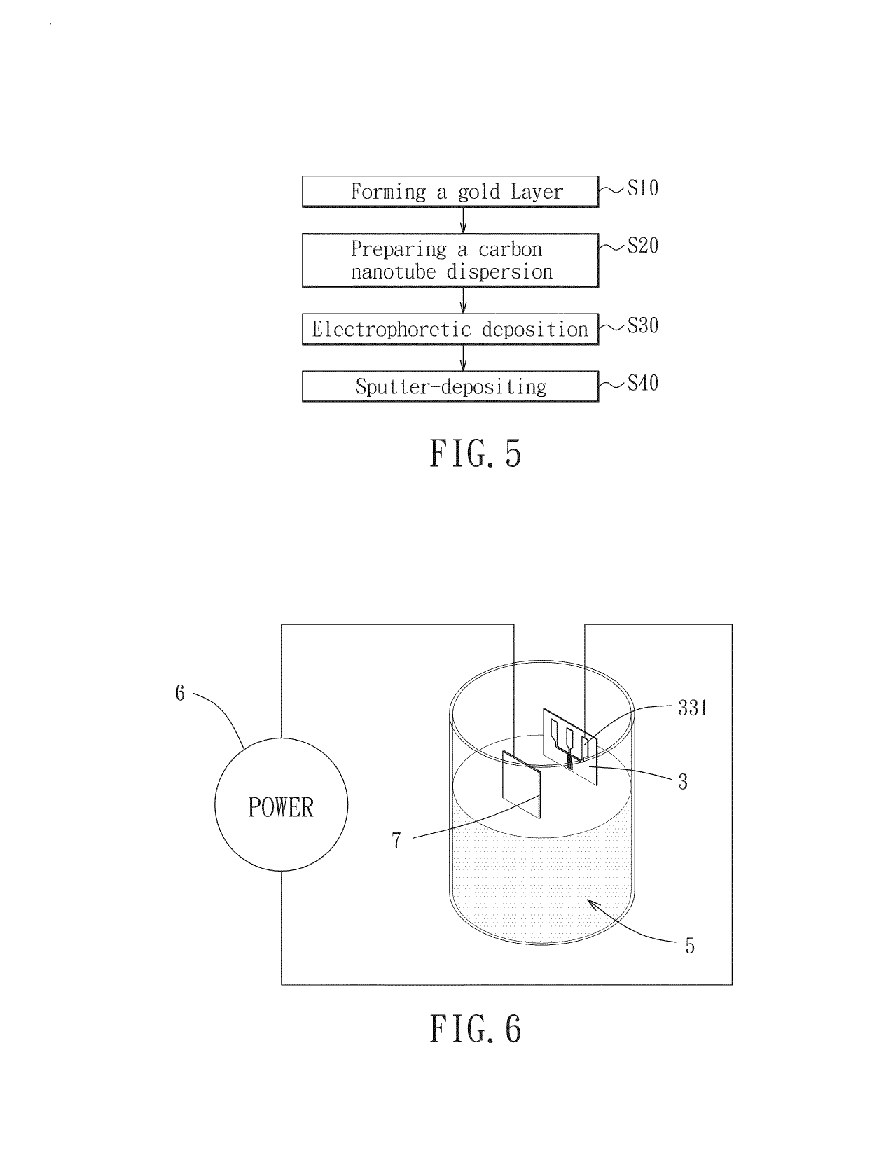

Referring to FIGS. 2, and 5, the sensing electrode unit 3 is fabricated as follows:

In step S10, three patterned gold strips are formed at intervals on the substrate plate 211 with a thickness of about 400 nm by photolithography to form the conducting layers (gold) 311, 321, and 331, and contact pads 217, 218 and 219 which are connected to the conducting layers 311, 321, 331, respectively. Ag/AgCl is electroplated on the conducting layer 311 of the reference electrode 31.

In step S20, a carbon nanotube dispersion is prepared. Carbon nanotubes are preferably multi-wall carbon nanotubes with 10-240 nm in diameter, and may be synthesized from a gaseous body including hydrocarbon compounds, such as CH₄, C₂H₂, C₂H₄, C₆H₆, etc., by chemical vapor deposition. In an embodiment, the carbon nanotube dispersion contains 0.55 gm of carbon nanotubes and 1 ml of deionized water and is subjected to sonification for dispersing the carbon nanotubes homogeneously.

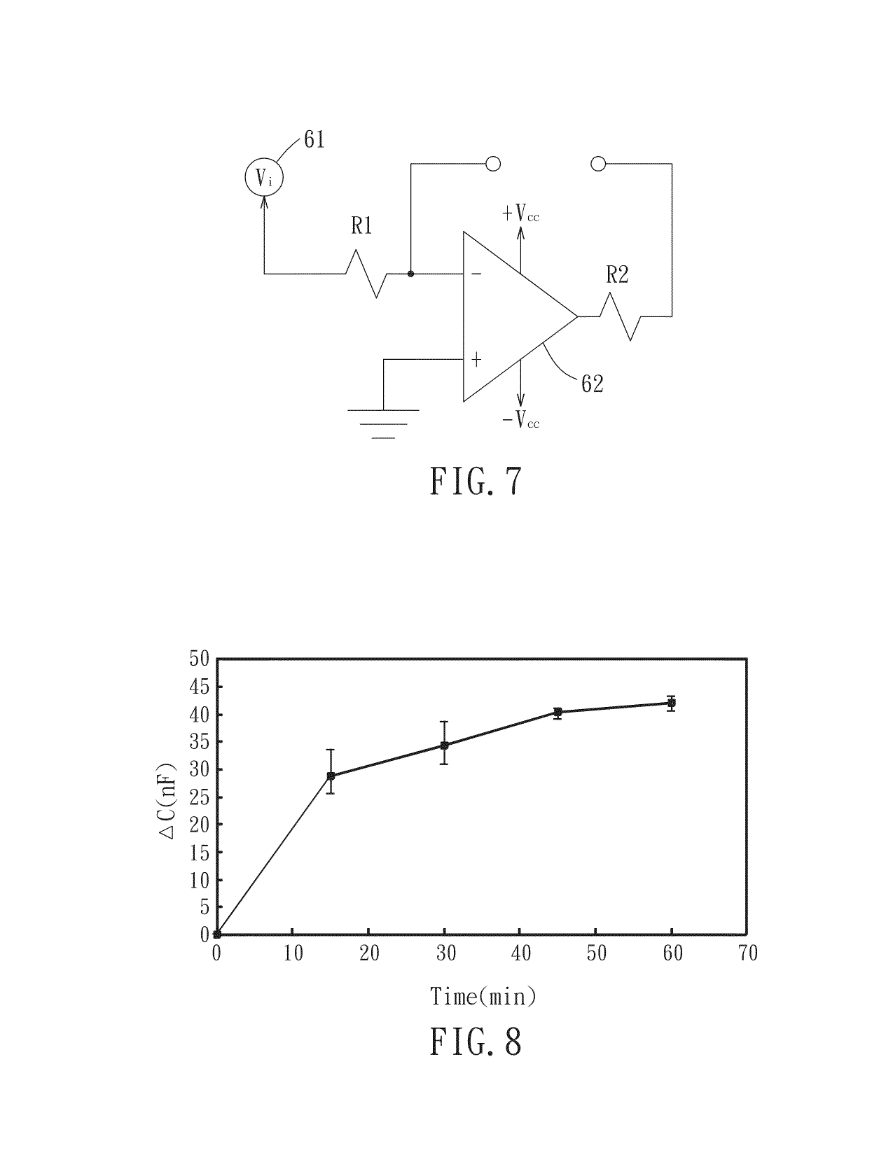

Referring to FIGS. 2, 6 and 7, in step S30, the carbon nanotubes are electrophoretically deposited on the conducting layer 331 (gold) of the working electrode 33. For electrophoretic deposition, an anode 7 is connected to a power unit 6 and is disposed in the carbon nanotube dispersion 5. The sensing electrode unit 3 is dipped into the carbon nanotube dispersion 5, and the conducting layer 331 is connected to the power unit 6.

The power unit 6 includes a power source 61, a calculation amplifier 62, a first resistor R1 and a second resistor R2. The negative pole of the calculation amplifier 62 is connected to the power source 61 through the first resistor R1, and is connected further to the anode 7. The positive pole of the calculation amplifier 62 is grounded. The conducting layer 331 of the working electrode 33 of the sensing electrode unit 3 is connected to an output end of the calculation amplifier 62 through the second resistor R2. The negative and positive poles of the calculation amplifier 62 have the same potential. As such, if the voltage supplied to the anode 7 by the power source 61 is constant, the current supplied from the power source 61 will be constant, and the rate of depositing carbon nanotubes on the conducting layer 331 of the working electrode 33 can be kept constant. In an embodiment, the voltage applied by the power source 61 is 5V, the output current is 0.5 mA, the output power is 2.5 mW, and the current density 33.3 mA/sq·mm. The first resistor R1 has 10 k ohm, the second resistor R2 is 1 k ohm. The distance between the anode 7 and the sensing electrode unit 3 is 5 mm.

The period of electrophorectic deposition may be optimized based on the capacitance change on the surface of the deposited carbon nanotube layer on the working electrode 33. Referring to FIG. 8, when the deposition period is less than 30 minutes, the amount of capacitance change is large because of the differing deposited thickness of carbon nanotubes due to the varying dispersion condition of the carbon nanotube dispersion. When the deposition period is larger than 45 min, the capacitance change becomes stable. Because the power supply is constant, even the deposition period is increased further, the thickness of the carbon nanotubes does not change easily. For a power of 2.5 mW, the preferred deposition period is 45 min.

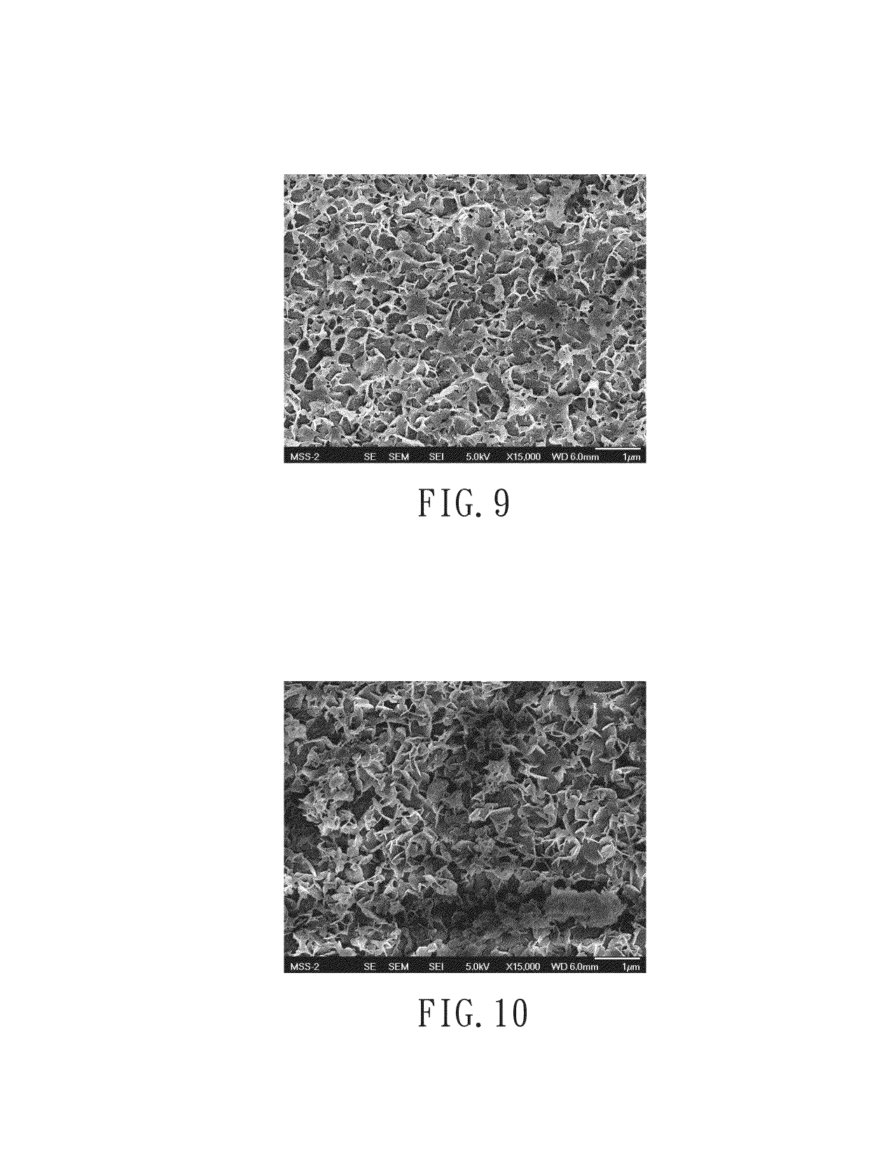

Referring to FIGS. 9 and 10, SEM images show that the surface structure of the carbon nanotube layer 332 deposited on the conducting layer (bare gold) 331 does not change much before and after the carbon nanotube layer 332 is washed. The thickness of the carbon nanotube layer 332 is evaluated using an optical instrument. The thickness is substantially the same before and after the carbon nanotube layer 332 is washed.

In step S40, a gold nanoparticle layer are sputter-deposited on the carbon nanotube layer 332 by a vapor deposition method in which argon ions are used to bombard a target material (gold). In an embodiment, the current for sputtering is 30 A, and the thickness of the sputter coated gold nanoparticle layer is 20 nm.

### Adhesion Test

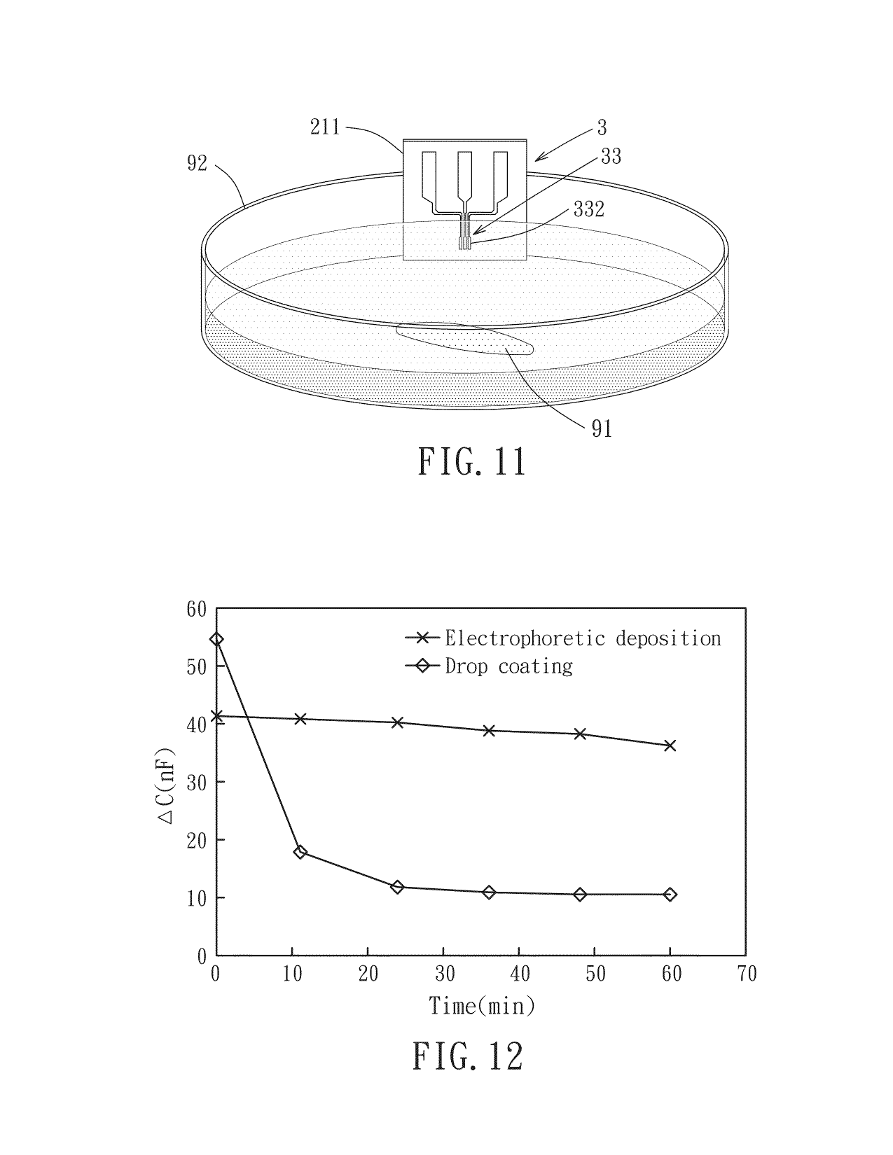

An adhesion strength of the electrophoretically deposited carbon nanotube layer 332 to the conducting layer 331 was investigated and was compared with a carbon nanotube layer deposited by a drop coating method disclosed in the prior art. Referring to FIG. 11, in the adhesion test, the sensing electrode unit 3 is disposed in proximity to a circumferential wall of a glass container 92 that contains deionized water. A turbulent flow was created by a rotor 91 rotating at 200 rpm inside the glass container 92 to stir the deionized water and to wash and shear the carbon nanotube layer 332. The capacitance change occurring at the surface of the carbon nanotube layer 332 was measured periodically. A similar test was conducted for the carbon nanotube layer deposited by drop coating.

Referring to FIG. 12, the capacitance change for the carbon nanotube layer 332 decreases slowly as the stirring period increases, and the capacitance change for the carbon nanotube layer deposited by drop coating decreases rapidly as the stirring period increases. Compared to the carbon nanotube layer deposited by drop coating, the electrophoretically deposited carbon nanotube layer 332 of the present invention has an adhesion strength higher than and a surface structure more uniform than that of the carbon nanotube layer deposited by drop coating.

### Evaluation of Drug Release Profile

The sensor chip 100 may be used to detect a drug released from nanocapsules so as to evaluate a drug release profile of the nanocapsules. Especially, the sensor chip 100 is suitable for the detection of an antibiotic drug, such as teicoplanin, released from antibiotic nanocapsules.

In an experiment, teicoplanin nanocapsules were dissolved in a phosphate buffered saline (PBS) solution to prepare nanocapsule samples. The concentrations of the nanocapsule samples were 15% and 20%. 10 μl of each sample was injected into the first injection hole 215. 90 μl of a PBS solution was injected into the second injection hole 216 to cause teicoplanin drug released from the teicoplanin nanocapsules to flow into the measure region 226 through the passage 231. The partition piece 23 prevents the teicoplanin nanocapsules from flowing into the measure region 226 and from contaminating the sensing electrode unit 3. Cyclic voltammetry was conducted for electrochemical measurements.

For comparison with the working electrode 33 according to the present invention, cyclic voltammetry electrochemical measurements were also conducted using a working electrode having only a bare gold layer, a working electrode having only a carbon nanotube layer deposited on a bare gold layer by drop coating, and a working electrode having only a carbon nanotube layer electrophoretically deposited on a bare gold layer.

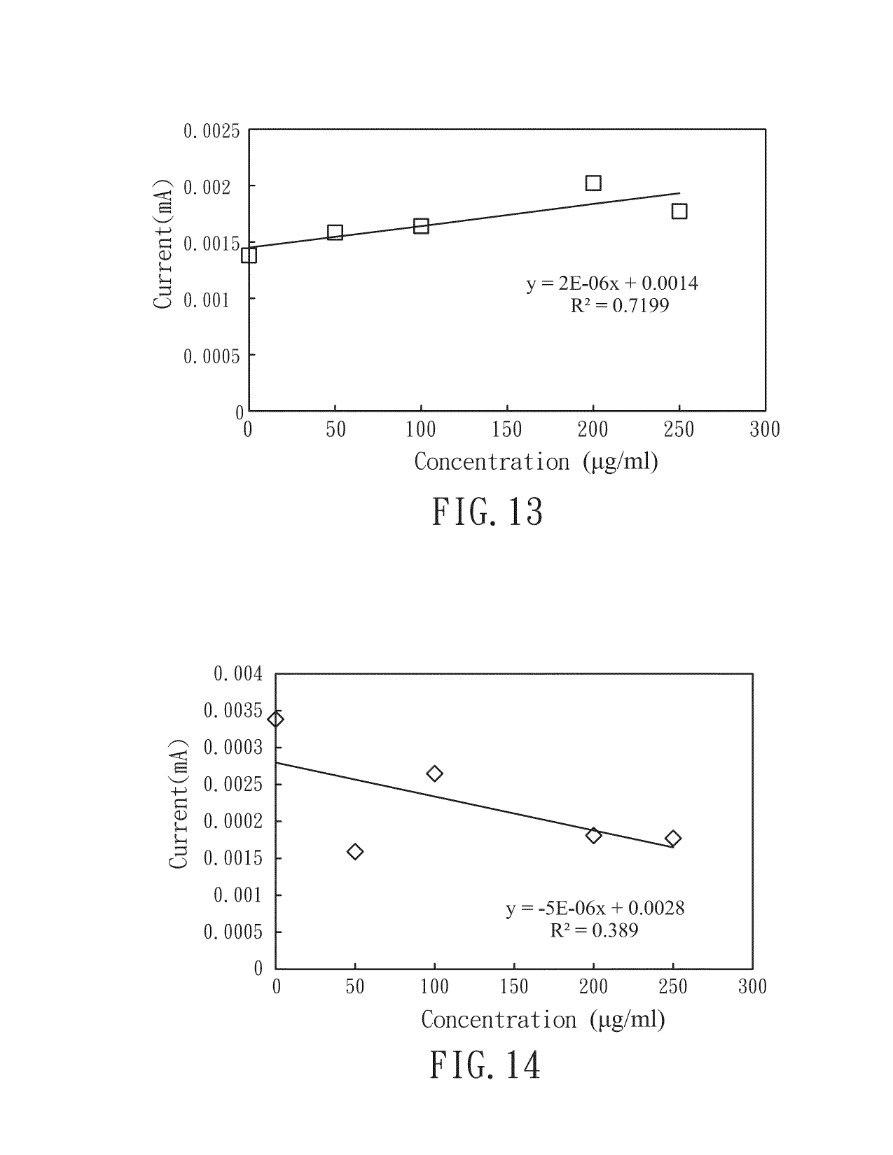

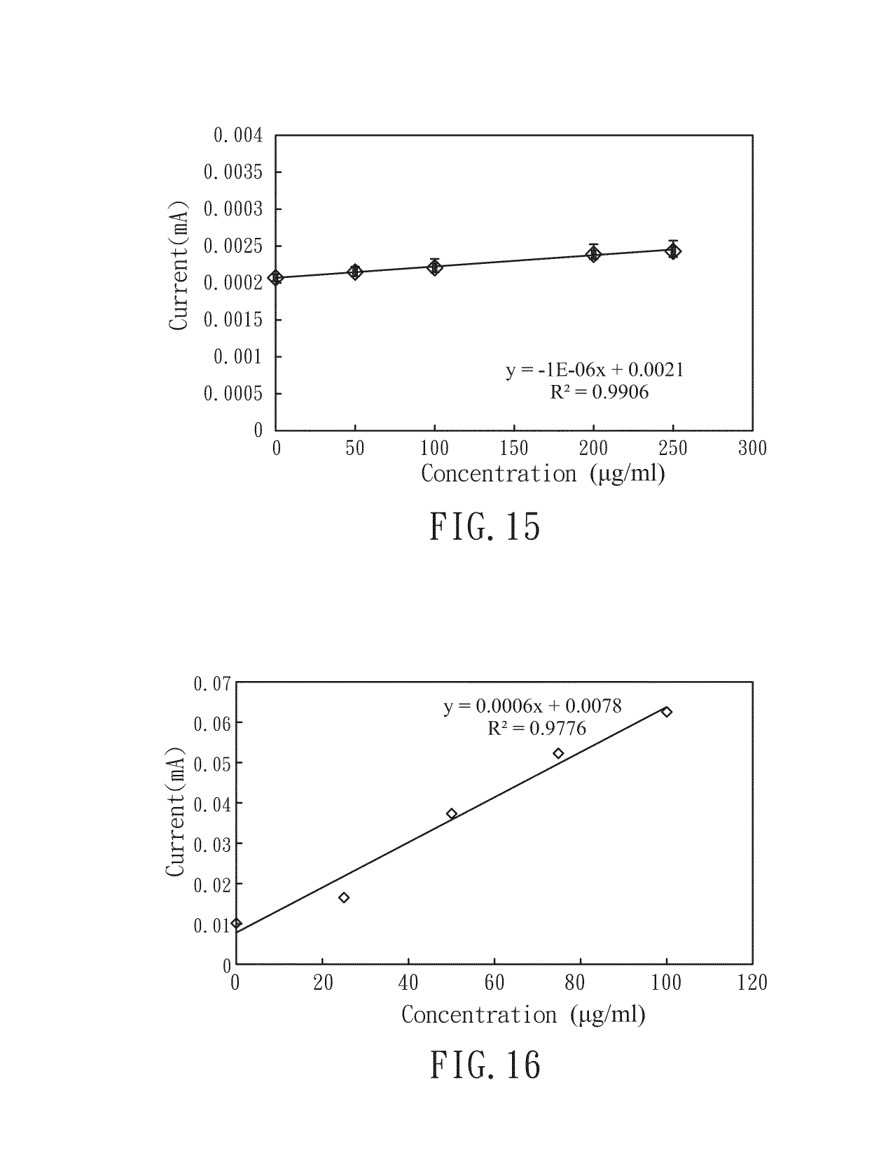

Current values obtained from the electrochemical measurements were plotted as a function of teicoplanin concentration. The resulting graphs are shown in FIGS. 13 to 16. Referring to FIGS. 13 to 16, the slope values of the graphs for the bare gold layer electrode, for the electrode having the carbon nanotube layer deposited by drop coating, for the electrode having only the electrophoretically deposited carbon nanotube layer on a gold layer, and for the working electrode 33 of the present invention are 2.38×10⁻⁶ mA·(ml/μg) (FIG. 13), −5×10⁻⁶ mA·(ml/μg) (FIG. 14), 1×10⁻⁶ mA·(ml/μg) (FIG. 15) and 5.32×10⁻⁴ mA·(ml/μg) (FIG. 16), respectively. The graph of the electrode having only the electrophoretically deposited carbon nanotube layer on the gold layer has a slope value smaller than that of the bare gold layer electrode. The graph of the electrode of the present invention has a slope value higher than that of the bare gold layer electrode. The results indicate that the sensitivity of the electrode having only the electrophoretically deposited carbon nanotube layer is lower than that of the bare gold layer electrode and that the sensitivity of the electrode of the present invention is higher than that of the bare gold layer electrode. Although the electrode having only the electrophoretically deposited carbon nanotube layer has a relatively high surface area compared to the bare gold layer electrode, the catalytic activity thereof is lower than that of the bare gold layer electrode so that the sensitivity thereof is relatively low.

Compared to the bare gold electrode, the sensitivity of the electrode of the present invention increases 223.86 times (from 2.38×10⁻⁶ mA·(ml/μg) to 5.32×10⁻⁴ mA·(ml/μg). In sensing signals, the peak to peak current increases 38.267 times (from 0.001638 mA to 0.06268 mA). Amplification of the signals is 38.267 times. The linear range of teicoplanin concentration is 1 (μg/ml) to 100 (μg/ml).

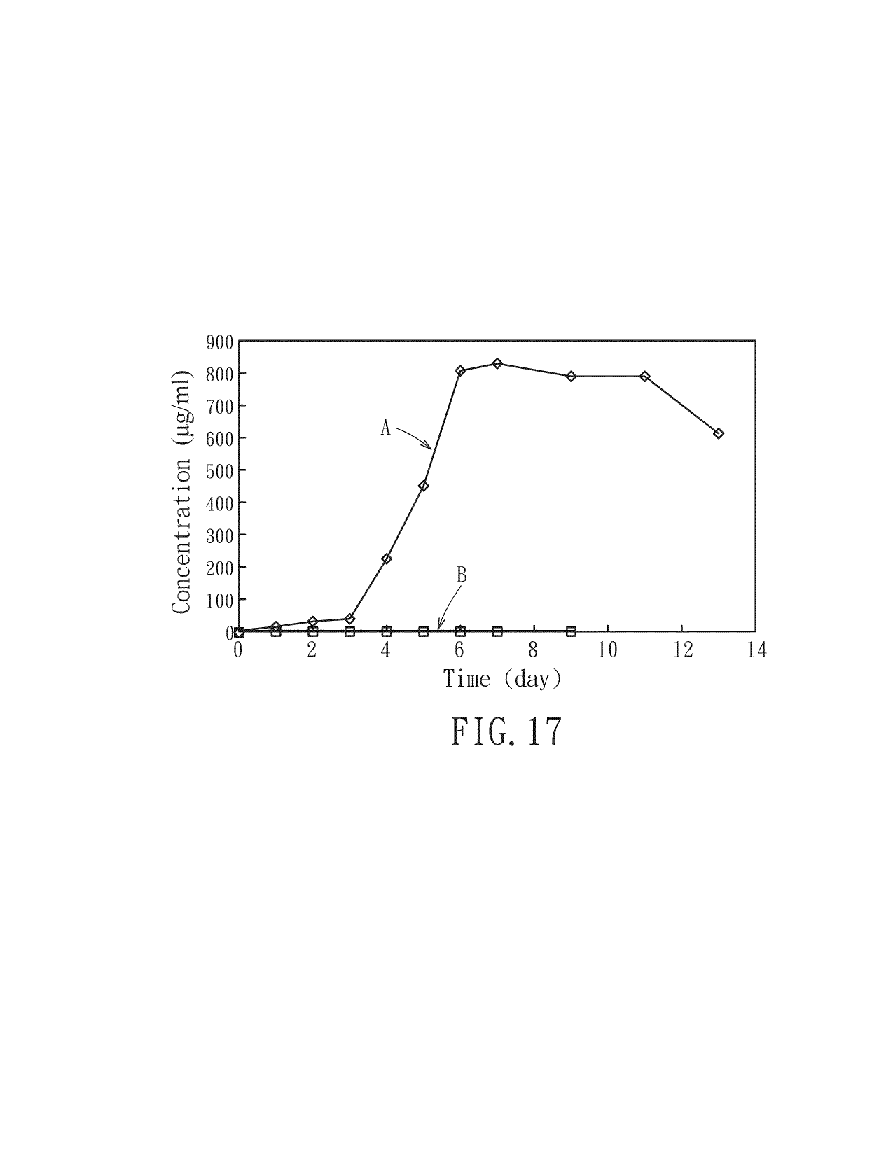

Referring to FIG. 17, in graph (A), concentration values of teicoplanin were plotted as a function of duration for a nanocapsule sample containing teicoplanin. Graph (B) is prepared for a nanocapsule sample which has no teicoplanin. In long-term sensing of the nanocapsule samples, graph (A) demonstrates that the drug release rate increases significantly on the third day, and the release of drug reaches 800 μg/ml on the 7^{th} day.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A working electrode, comprising:
a conducting layer;
a carbon nanotube layer electrophoretically deposited on said conducting layer; and
a gold nanoparticle layer sputter-deposited on said carbon nanotube layer.

2. The working electrode of claim 1, wherein said carbon nanotube layer has a thickness of 200-500 nm.

3. The working electrode of claim 1, wherein said carbon nanotube layer includes multiwall carbon nanotubes.

4. The working electrode of claim 1, wherein said conducting layer is a gold layer.

5. A method of making a working electrode, comprising:
forming a conducting layer on a substrate;
electrophoretically depositing a carbon nanotube layer on the conducting layer; and
depositing a gold nanoparticle layer on the carbon nanotube layer.

6. The method of claim 5, wherein the depositing of the carbon nanotube layer includes the steps of:
preparing a dispersion of carbon nanotubes using a sonicator; and depositing the carbon nanotubes from the dispersion onto the conducting layer by electrophoresis.

7. The method of claim 6, wherein the depositing of the carbon nanotube layer is conducted under constant current.

8. The method of claim 5, wherein the gold nanoparticle layer is sputter deposited on the carbon nanotube layer.

9. A sensor chip for detecting a drug released from nanocapsules in a solution, comprising
a housing unit including a micro-channel, a partition piece, an extraction hole, and an injection hole unit, said micro-channel having an injection region communicated with said injection hole unit and adapted to receive the nanocapsules and the solution, an extraction region communicated with said extraction hole, and a measure region disposed between said injection region and said extraction region, said partition piece being disposed in said injection region for preventing the nanocapsules from flowing to the measure region while permitting the drug to flow to the measure region; and
a sensing electrode unit disposed in said housing unit and including a working electrode exposed to said measure region.

10. The sensor chip of claim 9, wherein said working electrode has a conducting layer, a carbon nanotube layer formed on said conducting layer and a gold nanoparticle layer formed on said carbon nanotube layer.

11. The sensor chip of claim 9, wherein said housing unit has a lower housing part, and an upper housing part stacked on said lower housing part, said lower housing part having said micro-channel, said upper housing part having a substrate plate, and first and second cover parts respectively disposed at two opposite sides of said substrate plate, said sensing electrode unit being formed on said substrate plate, said first cover part covering said extraction region and having said extraction hole, said second cover part covering said injection region and having said injection hole unit.

12. The sensor chip of claim 11, wherein said substrate plate is made of glass, and said lower housing part, and said first and second cover parts are made of a plastic material.

13. The sensor chip of claim 10, wherein said conducting layer of said working electrode is a gold layer.

14. The sensor chip of claim 9, wherein said partition piece is disposed across said injection region and defines a passage for permitting the drug to flow therethrough.

15. The sensor chip of claim 14, wherein said partition piece divides said injection region into first and second regions, said first region being distal from said measure region, said second region being proximate to said measure region and interposing between said first region and said measure region, said passage connected fluidly between said first and second regions.

16. The sensor chip of claim 15, wherein said injection hole unit includes two spaced apart first and second injection holes, said first injection hole being aligned with said first region, said second injection hole being aligned with said passage.

17. The sensor chip of claim 16, wherein said injection region has an injection region wall surrounding said injection region, and said partition piece has one end contacting a portion of said injection region wall, and another end spaced apart from said injection region wall to define said passage together with said injection region wall.
